(19) United States
(12) Patent Application Publication
(10) Pub. No.: US 2006/0055065 A1
(43) Pub. Date: Mar. 16, 2006

(54) HV-MOS and mixed-signal circuit structure with low-k interconnection

(75) Inventors: Chi-Wen Liu, Hsinchu (TW); Kuo-Ching Chiang, Tao-Yuan City (TW); Horng-Huei Tseng, Hsin-Chu (TW); Syun-Ming Jang, Hsin-Chu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 10/938,480

(22) Filed: Sep. 10, 2004

(51) Int. Cl. H01L 31/109

(52) U.S. Cl. 257/903

(57) ABSTRACT

A semiconductor chip comprises a fast device formed on a semiconductor substrate and a high-voltage metal-oxide-semiconductor transistor (HV-MOS) formed on the semiconductor substrate and an interconnect isolation feature having a low-k dielectric material disposed over the fast device and the HV-MOS in the semiconductor substrate.

### BACKGROUND

Integrated circuits (IC) technologies have advanced beyond 0.09 micron technologies node. IC technologies not only progressed in feature size and integration density but also in integrating various semiconductor devices into one chip (or die). In system-on-chip (SOC) technologies, different types of microelectronic devices such as logic devices, analog devices, memory arrays, and high voltage devices may be integrated into one monolithic semiconductor wafer aimed for improved circuit performance, reliability, manufacturing cycle time, cost, device speed, and other advantages. For example, high voltage metal-oxide-semiconductor (HV-MOS) devices and mixed-signal circuit may be combined together for applications including liquid crystal drive ICs (LDI) for liquid crystal displays (LCD). However, RC delay may reduce device speed and degrade system performance.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a sectional view of one embodiment of an exemplary integrated circuit.

FIG. 2 is a sectional view of one embodiment of a liquid crystal display (LCD) device within which the integrated circuit of FIG. 1 may be incorporated.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

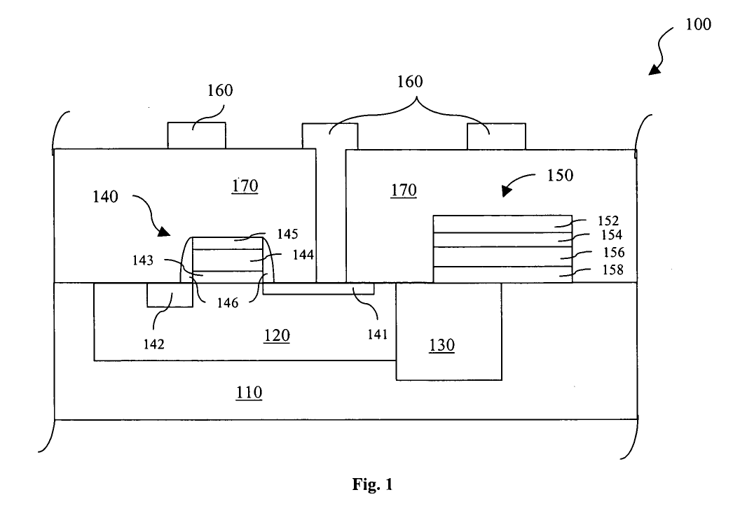

FIG. 1 is a sectional view of one embodiment of an exemplary integrated circuit 100. The integrated circuit 100 may be a SOC chip and may comprise various microelectronic devices. The integrated circuit 100 may comprise a substrate 110. The substrate 110 may be an elementary semiconductor such as silicon, germanium, and diamond. The substrate 110 may also comprise a compound semiconductor such as silicon carbide, gallium arsenic, indium arsenide, and indium phosphide. The substrate 110 may also comprise an alloy semiconductor such as silicon germanium, silicon germanium carbide, gallium arsenic phosphide, and gallium indium phosphide. The substrate 110 may include an epitaxial layer over a bulk semiconductor. Furthermore, the substrate may be strained for performance enhancement. For example, the epitaxial layer may comprise semiconductor materials different from those of the bulk semiconductor such as a layer of silicon germanium overlying a bulk silicon, or a layer of silicon overlying a bulk silicon germanium formed by a process such as selective epitaxial growth (SEG). Furthermore, the substrate 110 may comprise a semiconductor-on-insulator (SOI) structure. For examples, the substrate may include a buried oxide (BOX) layer formed by a process such as separation by implanted oxygen (SIMOX). The substrate 110 may comprise a glass material such as one in thin film transistor (TFT) technologies. The substrate 110 may comprise a p-type doped region and/or an n-type doped region. Doped regions may have different dopant type, doping concentration, and doping profile. Doping may be implemented by a process such as ion implantation or another suitable method.

The substrate 110 may also comprise a well structure 120. The well structure 120 may be a P-well or an N-well structure, which can be fabricated directly onto or within the substrate 110. In general, the substrate 110 may comprise N-well and/or P-well regions. N-well and/or P-well regions may have a retrograde doping profile. The well structure 120 is provided only as an example and is not meant to limit the disclosure in any manner.

The substrate 110 may further comprise an isolation feature 130 to separate different devices formed on the substrate. The isolation feature 130 may be formed using a varieties of manufacturing technologies. For example, the isolation feature 130 may comprise junction isolation, field isolation, dielectric isolation such as local oxidation of silicon (LOCOS) and shallow trench isolation (STI), or other suitable isolation structures. In one example, LOCOS isolation structures may be recessed into the substrate and formed by thermal oxygen oxidation, steam oxidation, or another suitable process.

The integrated circuit 100 may comprise various microelectronic devices formed in the substrate 110. For example, the integrated circuit 100 may comprise an exemplary high voltage metal-oxide-semiconductor (HV-MOS) transistor 140. The HV-MOS 140 may be used in applications wherein 30 volts or higher power supply is provided during operation. The HV-MOS 140 may comprise a double diffused drain (DDD) region, lateral double diffused MOS (LDMOS) structure, or vertical double diffused MOS (VDMOS). The HV-MOS 140 may be formed by BiCMOS (stands for Bipolar-CMOS ) process, or BCD technologies (stands for Bipolar-CMOS-DMOS). The HV-MOS 140 may be formed in the well structure 120 and have a junction depth less than about 60 nanometer. The HV-MOS transistor 140 may comprise a source 141 and a drain 142. In one embodiment, one of source and drain is formed in a DDD structure. For example, the drain 142 may comprise a DDD structure while the source may comprise conventional source structure. The conventional source region may comprise a light doped drain (LDD) feature. In another embodiment, both source and drain are formed in a DDD structure. The DDD structure may comprise a different doping profile and may be formed by two ion implantation steps. The first doping process may have a lower doping concentration ranging from about 10¹³ to about 5×10¹⁴ ion/cm². The first doping dimension may be extended to the outline of the gate electrode. The second doped region may be encompassed by the first doping region and may be offset by gate spacers from the gate electrode. The second doping region may have a higher doping concentration ranging from about 10¹⁵ to about 5×10¹⁵ ion/cm². The DDD structure can provide a high breakdown voltage for the HV-MOS transistor 140.

The HV-MOS transistor 140 may further comprise a gate stack formed on the well structure 120 interposing the source 141 and the drain 142. The gate stack may include a gate dielectric 143 formed on the well structure 120. The gate dielectric 143 may include silicon oxide, silicon oxynitride, or a high dielectric-constant (k) material such as hafnium oxide, hafnium silicide, zirconium oxide, aluminum oxide, silicon nitride, tantalum pentoxide, or combinations thereof. The gate dielectric 143 may be formed by thermal oxide, atomic layer deposition (ALD), chemical vapor deposition (CVD), physical vapor deposition (PVD), or other suitable processing.

The gate stack also comprises a gate electrode 144, disposed over the gate dielectric 143. The gate electrode 144 may comprise polycrystalline silicon (poly-Si), metal such as Al. Cu, W, Ti, Ta, TiN, TaN, NiSi, CoSi, and/or other conductive material. The gate electrode 144 may be formed by CVD, PVD, plating, ALD, and/or other suitable processes. The gate stack may further comprise a contact layer 145 disposed over the gate electrode 144 to reduce contact resistance and improve performance. The contact layer 145 may comprise metal silicide such as nickel silicide, cobalt silicide, tungsten silicide, tantalum silicide, and titanium silicide. The contact layer 145 may be formed by CVD, PVD, or ALD. In one example, silicide may be formed by a self-aligned silicidation process. The HV-MOS transistor 140 may also include gate spacers 146 positioned on both sides of the gate stack. The gate spacers 146 may comprise silicon nitride, silicon oxide, silicon carbide, silicon oxynitride, or combinations thereof. The gate spacers 146 may have multilayer structure and may be formed by depositing dielectric material and then anisotropically etching back.

The integrated circuit 100 may also include a fast device such as a radio-frequency (RF) device or other high frequency device such as silicon bipolar transistor or silicon germanium heterojunction bipolar transistor (HBT). The fast device may have a channel length less than 0.13 micron. The fast device may include at least one capacitor such as a capacitor 150. Due to the desire to increase integration density, the capacitor 150 may be positioned at least partially atop of the isolation feature 130 of the HV-MOS device 140. The capacitor 150 may comprise a top electrode 152, a bottom electrode 156, and a dielectric layer 154 interposing between the top and bottom electrodes. The top electrode 152 and/or the bottom electrode 154 may comprise metal, metal compound, metal alloy, and combinations thereof. The metal used for the electrodes may include aluminum, copper, titanium, tantalum, tungsten, metal silicide, or combinations thereof. The top electrode 152 and/or the bottom electrode 154 may alternatively comprise polysilicon, amorphous silicon, and combinations thereof. The top and bottom electrodes 152 and 156 may each comprise both metal-based material and silicon-based material, and may further comprise metal silicide. The capacitor electrodes 152 and 156 may be formed by CVD, PVD, plating, and other suitable processing. The capacitor dielectric layer 154 may comprise a dielectric material such as silicon oxide, silicon nitride, silicon oxynitride, FSG, low-k material, high-k material, or combinations thereof, and may be formed by CVD, PVD, spin-on polymer (SOP), or other suitable processing. The capacitor may be separated and isolated from the substrate by another dielectric layer 158, which is formed by CVD, PVD, thermal oxidation, or SOP. The dielectric layer 158 may be formed simultaneously with gate dielectric layer 143, for example.

The integrated circuit 100 may further include a multilayer interconnect 160 to route electric signals and link the microelectronic devices to form functional circuits. The interconnect 160 may include contact features and via features for vertical interconnections, and one layer or multilayer metal lines for horizontal interconnections. The interconnect 160 may comprise aluminum-based, tungsten-based, copper-based materials, or combinations thereof. For example, copper-based multilayer interconnect may comprise copper, copper alloy, titanium, titanium nitride, tantalum, tantalum nitride, tungsten, polysilicon, metal silicide, or combinations, as widely used for deep micron or deep submicron technologies. The copper multilayer interconnect may be formed using a dual damascene process. The multilayer interconnect may be formed by CVD, PVD, ALD, plating, or combinations thereof.

The integrated circuit 100 may comprise interconnect isolation material formed between metal layers (interlayer dielectric or ILD) and between the first metal layer and the substrate (pre-metal dielectric or PMD). The interconnect isolation material comprises low dielectric constant (k) material having dielectric constant below than 3.9, the dielectric constant of thermal silicon dioxide. Preferably, the low-k material used may have the dielectric constant ranging between about 3.8 and about 2.8. The low-k material may include fluorinated silica glass (FSG), carbon doped silicon oxide, combinations thereof, and/or other low-k material.

Other optional low-k materials may include Black Diamond® (Applied Materials of Santa Clara, Calif.), Xerogel, Aerogel, amorphous fluorinated carbon, Parylene, BCB (bis-benzocyclobutenes), SiLK (Dow Chemical, Midland, Mich.), polyimide, and/or other materials. The low-k material may be formed by CVD, ALD, PVD, spin-on coating (spin-on polymer or SOP), and/or other suitable processes. The interconnect isolation material may further comprise other dielectric material such as silicon oxide in combination with the low-k material and may adopt multilayer structure. The low-k material, while being used for interconnect isolation material, could reduce RC delay and enhance device speed.

The integrated circuit 100 may also include a plurality of memory cells such as static random-access memory (SRAM), dynamical random-access-memory (DRAM), non-volatile memory (NVM), ferroelectric memory (FRAM), magnetoresistive random-access memory (MRAM), resonant tunneling diode-based memory, single-electron memory, phase-change nonvolatile memory, protonic nonvolatile memory, and/or combinations thereof.

Furthermore, the integrated circuit 100 may comprise a variety of microelectronic devices formed in the semiconductor substrate, in addition to HV-MOS devices, fast devices having a capacitor, and memory arrays. These microelectronic devices may be isolated from each other through isolation features such as the isolation feature 130. The microelectronic devices may include, but are not limited to, passive components such as resistors such as thin film resistor, trimmable resistor, and diffused transistor, and inductors. The microelectronic devices may also comprise active components such as NPN bipolar transistors, PNP bipolar transistor, complementary bipolar transistor, Zener diode, Schottky diode, NMOS, PMOS, complementary MOS (CMOS), or other devices. The semiconductor manufacturing technologies involved to fabricate the same may include CMOS technologies, BiCMOS technologies, BCD, or other suitable manufacturing technologies.

The integrated circuit 100 may be used in various applications. For example, the integrated circuits may be used as a LC drive IC (LDI). The integrated circuits 100 may be used in other areas including wireless handsets, digital set-top boxes, global positioning system, fiber optical communication system.

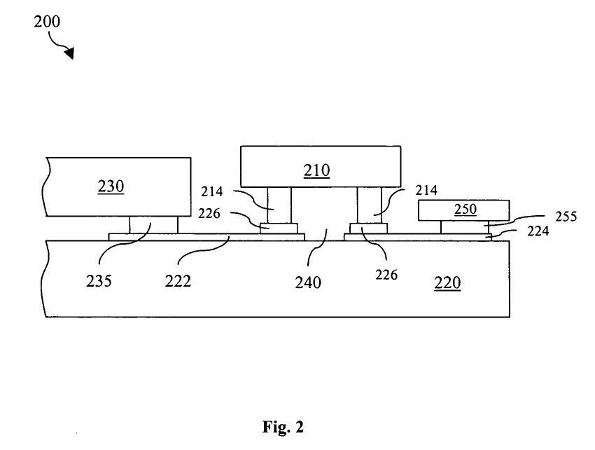

Referring to FIG. 2, illustrated is a sectional view of one embodiment of an LCD device 200 in which the integrated circuit 100 of FIG. 1 may be incorporated. The LCD device 200 is only one example of a device in which the integrated circuit 100 having a low-k interlayer dielectric isolation. The LCD device 200 may comprise an IC chip 210 having a structure similar to the integrated circuit 100 illustrated in FIG. 1. The IC chip 210 may have a high voltage MOS transistor, a fast device including at least one capacitor, and low-k materials used for ILD and PMD. The IC chip 210 may further comprise a plurality of memory arrays (or cells). The IC chip 210 may be a LC drive IC. The IC chip 210 may further include bump features 214. The bump features may have multiple layers of different metals such as an adhesion layer, a diffusion barrier layer, a solderable layer, and an oxidation barrier layer. The bump features may comprise titanium, chromium, aluminum, copper, nickel, vanadium, gold, or combinations thereof

The LCD device 200 may include a LCD glass substrate 220 and an upper glass 230. The LCD glass substrate 220 may also have a plurality of glass electrodes 222 and 224 formed on the surface of the LCD glass substrate to control LC cells. The upper glass 230 may also have a plurality of glass electrodes substantially similar to 222 and 224 to control LC cells. Liquid crystal material is filled between the LCD glass substrate 220 and the upper glass 230 and is sealed inside. The LCD glass substrate 220 and the upper glass 230 comprise translucent or transparent glass and may each further include a polarizer layer and an alignment layer (not shown). The glass electrodes are patterned and connected to each LCD cell and control the cell's display functions. The glass electrodes 222 and 224 may comprise a transparent conductive material such as indium tin oxide (ITO). The glass electrodes in the upper glass 230 may be electrically routed to the LCD glass substrate 220 through a conductive crossover feature 235 or a plurality of crossover features. The glass electrodes may include bonding features 226 configured for IC chip bonding.

The IC chip 210 may be bonded to the LCD glass substrate 220 through the bumps 214 and the bonding features 224 using an anisotropic conductive film (ACF) 240. The LCD device 200 may further include a flexible printed circuit (FPC) 250 bonded to glass electrodes 224 of the LCD glass substrate 220 through another bonding feature 255 at one end and connected to equipment such as a display controller at another end. It is understood that the LCD device 200 demonstrates one of many possible applications of the integrated circuit 100 (and also the IC chip 210).

In general, the disclosed SOC chip ( such as the integrated circuit 100 or the IC chip 210) may comprise at least one high voltage MOS transistor, at least a fast device including a capacitor, and low-k materials used for interlayer dielectric. The low-k materials may have dielectric constant below 3.9, or more commonly ranging from about 2.8 to about 3.8. The low-k material may comprise FSG and/or carbon doped silicon oxide, and/or other low-k material. The SOC chip may further comprise one or a plurality of memory arrays formed in the substrate such as static random-access memory (SRAM), dynamical random-access-memory (DRAM), non-volatile memory (NVM), ferroelectric memory (FRAM), magnetoresistive random-access memory (MRAM), resonant tunneling diode-based memory, single-electron memory, phase-change nonvolatile memory, protonic nonvolatile memory, and/or combinations thereof.

Furthermore, the integrated circuit 100 may comprise a variety of microelectronic devices formed in the same substrate, each being isolated from others through isolation features such as STI and LOCOS. In addition to HV-MOS devices, fast devices having a capacitor, and memory arrays, the microelectronic devices may include, but are not limited to, passive components such as resistors such as thin film resistor, trimmable resistor, diffused transistor, metal inductors, and poly-Si inductors. The microelectronic devices may also comprise active components such as NPN bipolar transistors, PNP bipolar transistor, complementary bipolar transistor, Zener diode, Schottky diode, NMOS, PMOS, complementary MOS (CMOS), or other devices. The semiconductor manufacturing technologies involved to fabricate the same may include CMOS technologies, BiCMOS technologies, BCD, or other suitable manufacturing technologies. The SOC chip may have reduced RC delay and may be used in LC drive circuit, and other proper applications.

Although embodiments of the present disclosure have been described in detail, those skilled in the art should understand that they may make various changes, substitutions and alterations herein without departing from the spirit and scope of the present disclosure. Accordingly, all such changes, substitutions and alterations are intended to be included within the scope of the present disclosure as defined in the following claims. In the claims, means-plus-function clauses are intended to cover the structures described herein as performing the recited function and not only structural equivalents, but also equivalent structures.

What is claimed is:

1. A semiconductor chip comprising:
a fast device formed on a substrate;
a high-voltage metal-oxide-semiconductor transistor (HV-MOS) formed on the substrate; and
an interconnect isolation feature having a low-k dielectric material disposed over the fast device and the HV-MOS in the substrate.

2. The semiconductor chip of claim 1 wherein the low-k material has dielectric constant below 3.9.

3. The semiconductor chip of claim 1 wherein the low-k material has dielectric constant ranging from about 3.8 to about 2.8.

4. The semiconductor chip of claim 1 wherein the low-k material is selected from the group consisting of fluorinated silica glass (FSG), carbon doped silicon oxide, and combinations thereof.

5. The semiconductor chip of claim 1 wherein the low-k material is selected from the group consisting of FSG, carbon doped silicon oxide, Black Diamond®, Xerogel, Aerogel, amorphous fluorinated carbon, Parylene, bis-benzocyclobutenes (BCB), SiLK, polyimide.

6. The semiconductor chip of claim 1 wherein the low-k material is formed by a method selected from the group consisting of CVD, ALD, PVD, spin-on coating, and combinations thereof.

7. The semiconductor chip of claim 1 further comprising a plurality of memory arrays.

8. The semiconductor chip of claim 7 wherein the plurality of memory arrays comprise a static random-access-memory (SRAM), a dynamic random-access-memory (DRAM), a non-volatile-memory (NVM), and combinations thereof.

9. The semiconductor chip of claim 1 wherein the fast device has a channel length less than 0.13 micron.

10. The semiconductor chip of claim 1 wherein the fast device comprises at least one capacitor.

11. The semiconductor chip of claim 10 wherein at least one electrode of the at least one capacitor comprises a material selected from the group consisting of metal, metal compound, metal alloy, and combinations thereof.

12. The semiconductor chip of claim 10 wherein at least one electrode of the at least one capacitor comprises a material selected from the group consisting of polysilicon, amorphous silicon, and combinations thereof.

13. The semiconductor chip of claim 1 wherein the HV-MOS has an junction depth less than about 60 nanometer.

14. The semiconductor chip of claim 1 wherein the HV-MOS is used in applications where 30 volts or higher voltage is applied during operation.

15. The semiconductor chip of claim 1 wherein the HV-MOS comprises a structure selected from the group consisting of double diffused drain (DDD) feature, lateral diffused metal-oxide-semiconductor (LDMOS), and vertical diffused metal-oxide-semiconductor (VDMOS).

16. The semiconductor chip of claim 15 wherein the DDD feature is formed on one side of the HV-MOS.

17. The semiconductor chip of claim 15 wherein the DDD feature is formed on both sides of the HV-MOS.

18. The semiconductor chip of claim 1 wherein the HV-MOS is fabricated using Bipolar-CMOS (BiCMOS) technologies.

19. The semiconductor chip of claim 1 wherein the HV-MOS is fabricated using Bipolar-CMOS-DMOS (BCD) technologies.

20. The semiconductor chip of claim 1 further comprising interconnect formed on the semiconductor substrate.

21. The semiconductor chip of claim 19 wherein the interconnect comprises a material selected from the group consisting of tungsten-based, aluminum-based, copper-based materials, and combinations thereof.

22. The semiconductor chip of claim 1 wherein the semiconductor chip is used as liquid crystal display (LCD) driver circuit.

23. A method of forming a semiconductor chip comprising:
forming a fast device on a substrate;
forming a high-voltage metal-oxide-semiconductor transistor (HV-MOS) on the substrate; and
forming an interconnect isolation feature having a low-k material disposed over the substrate.

24. The method of claim 23 wherein forming the interconnect isolation feature having a low-k material comprises forming a low-k material by chemical vapor deposition (CVD).

25. The method of claim 23 wherein forming the interconnect isolation feature having a low-k material comprises forming a low-k material by spin-on.

26. The method of claim 23 wherein forming the interconnect isolation feature comprises forming fluorinated silica glass (FSG).

27. The method of claim 23 wherein forming the interconnect isolation feature comprises forming carbon doped silicon oxide.

28. The method of claim 23 further comprising forming a plurality of memory arrays.

29. The method of claim 23 further comprising forming interconnect by CVD, PVD, ALD, plating, or combinations thereof.

30. The method of claim 23 wherein forming the fast device comprising forming a capacitor.

31. The method of claim 30 wherein forming the capacitor comprising:
forming a bottom electrode on the semiconductor substrate;
forming a dielectric layer over the bottom electrode; and
forming a bottom electrode over the dielectric layer.

32. The method of claim 31 wherein forming the bottom and top electrodes comprising forming the bottom and top electrodes by one of CVD, PVD, ALD, and plating.

33. The method of claim 29 wherein forming the dielectric layer comprising forming the dielectric layer by one of CVD, PVD, ALD, and spin-on.
